(19) United States
(12) Patent Application Publication
(10) Pub. No.: US 2026/0107719 A1
(43) Pub. Date: Apr. 16, 2026

(54) PATTERNING SEMICONDUCTOR MATERIALS USING SURFACE MODIFICATION TECHNIQUES

(71) Applicant: Tokyo Electron Limited, Tokyo (JP)

(72) Inventors: Scott LEFEVRE, Albany, NY (US); Joshua BAILLARGEON, Albany, NY (US)

(21) Appl. No.: 18/898,479

(22) Filed: Sep. 26, 2024

(51) Int. Cl. H01L 21/308; H01L 21/02; H01L 21/3065

(52) U.S. Cl. CPC H10P 50/695; H10P 14/6532; H10P 50/242

(57) ABSTRACT

A method includes forming a mask over a semiconductor layer. The method includes first patterning the mask to form a first opening that exposes a first portion of the semiconductor layer. The method includes performing a plasma treatment to form a surface modification layer over the exposed first portion. The method includes second patterning the mask to form a second opening that exposes a second portion of the semiconductor layer, thereby forming a patterned mask that defines the first and second openings. The method includes performing an etching process to the semiconductor layer through the patterned mask to form a first trench extending from the first opening and a second trench extending from the second opening. The etching process removes the first portion at a first rate and the second portion at a second rate that is greater than the first rate.

### FILED OF THE DISCLOSURE

This disclosure relates to methods of manufacturing semiconductor devices and more particularly to methods of patterning semiconductor materials with improved etching selectivity and profile control.

### BACKGROUND

In the manufacture of a semiconductor devices (especially on the microscopic scale), various fabrication processes are executed, including, for example, film-forming depositions, etch mask creation, patterning, material etching and removal, and doping treatments. These processes are performed repeatedly to form desired semiconductor device elements on a substrate. In recent development, it has become increasingly important to merge and/or compact fabrication steps to reduce processing complexity, cost, and/or time. However, as device features continue to decrease in critical dimension (CD), many challenges arise with respect to performing one or more of the processes described above to achieve specific design goals. For example, increasingly sophisticated patterning schemes can require more complex stacks of materials and more iterations of lithography and etching processes to obtain features with wider ranges of dimensions. Such patterning schemes may be especially challenging in view of the ever-decreasing feature sizes and various etching defects occurring at such length scales.

### SUMMARY

Described herein are methods of implementing etching processes for forming semiconductor devices.

In one aspect, the present disclosure may provide a method that includes forming a mask over a semiconductor layer. The mask may be first patterned to form a first opening that exposes a first portion of the semiconductor layer. A plasma treatment may be performed to form a surface modification layer over the exposed first portion. The mask may be second patterned to form a second opening that exposes a second portion of the semiconductor layer, thereby forming a patterned mask that defines the first and second openings. An etching process may be performed to the semiconductor layer through the patterned mask to form a first trench extending from the first opening and a second trench extending from the second opening. The first portion may be removed by the etching process at a first rate and the second portion may be removed by the etching process at a second rate that is greater than the first rate.

In some implementations, first patterning the mask to form the first opening may include forming the first opening to a first width. In some implementations, second patterning the mask to form the second opening may include forming the second opening to a second width that is the same as the first width. In some implementations, performing the etching process may result in the first trench having a first depth and the second trench having a second depth that is greater than the first depth.

In some implementations, first patterning the mask to form the first opening may include forming the first opening to a first width. In some implementations, second patterning the mask to form the second opening may include forming the second opening to a second width that is the less than the first width. In some implementations, performing the etching process may result in the first trench having a first depth and the second trench having a second depth that is the same as the first depth.

In some implementations, performing the plasma treatment may include applying a plasma of a metal halide including tungsten and fluorine. In some implementations, performing a plasma treatment to form a surface modification layer may include performing a plasma treatment to form a surface modification layer that includes tungsten and silicon.

In some implementations, performing the etching process may cause the surface modification layer to be removed from the first trench.

In some implementations, the method may further include performing a second etching process to remove the surface modification layer from the first trench after performing the etching process.

In some implementations, the method may further include performing an oxidation process to treat the surface modification layer before performing the etching process.

In some implementations, the method may further include depositing a conductive layer to fill the first trench and the second trench.

In another aspect, the present disclosure may provide a method that includes forming a patterned mask over a semiconductor layer, the patterned mask defining a first opening to expose a first portion of the semiconductor layer. A first etching process may be performed to the semiconductor layer through the patterned mask, resulting in a first trench in the semiconductor layer at the first portion. A metal-containing plasma may be applied to form a metal silicide layer in the first trench at the first portion of the semiconductor layer. A second opening may be formed in the patterned mask to expose a second portion of the semiconductor layer proximate the first trench. A second etching process may be performed to the semiconductor layer through the patterned mask to selectively remove the second portion of the semiconductor layer at a higher rate than removal of the first portion of the semiconductor layer.

In some implementations, applying a metal-containing plasma may include applying a metal-containing plasma that includes a metal and a halogen. In some implementations, the metal including tungsten or molybdenum. In some implementations, the halogen may include chlorine or fluorine.

In some implementations, performing the second etching process may cause the metal silicide layer to be removed.

In some implementations, a third etching process may be performed to remove the metal silicide layer after the second etching process is performed. In some implementations, performing the second etching process may include performing a plasma-based etching process. In some implementations, performing the third etching process may include performing a plasma-less etching process. In some implementations, performing the second etching process may include performing a reactive ion etching (RIE) process.

In some implementations, the method may further include oxidizing the metal silicide layer to form a metal oxide layer in the first trench before performing the second etching process. In some implementations, applying a metal-containing plasma may include applying tungsten hexafluoride, the metal silicide layer including tungsten silicide, and the metal oxide layer including tungsten oxide.

In some implementations, forming a second opening may include forming a second opening in the patterned mask to expose a second portion of the semiconductor layer proximate the first trench.

In yet another aspect, the present disclosure may provide a semiconductor structure that includes a semiconductor layer and a conductive feature embedded in the semiconductor layer. The conductive feature may include a top surface, a first bottom surface, and a second bottom surface. The first bottom surface may be vertically separated from the top surface by a first height. The second bottom surface may be laterally proximate the first bottom surface and vertically separated from the top surface by a second height that is different from the first height. In some implementations, the second bottom surface may be laterally adjacent to the first bottom surface.

In some implementations, the conductive feature may include a first metal layer, a second metal layer, and a third metal layer. The first metal layer may extend vertically between the top surface and the first bottom surface. The second metal layer may extend vertically between the top surface and the second bottom surface. The third metal layer may extend vertically between the first metal layer and the first bottom surface.

In some implementations, the first metal layer and the second metal layer may have the same composition. In some implementations, the third metal layer may have a composition that is different from the first metal layer and the second metal layer. In some implementations, the third metal layer may include a metal silicide. In some implementations, the first metal layer and the second metal layer may extend tungsten, and the third metal layer may extend tungsten silicide. In some implementations, the second bottom surface may be laterally adjacent to the first bottom surface.

In still another aspect, the present disclosure may provide a semiconductor structure that includes a semiconductor layer and a conductive feature embedded in the semiconductor layer. The conductive feature may include a first metal layer, a second metal layer, and a third metal layer. The third metal layer may be vertically below and in direct contact with the first metal layer. The second metal layer may be in direct contact with the first metal layer and laterally proximate the first metal layer and the third metal layer. The first metal layer and the second metal layer may have the same composition. The third metal layer may have a composition that is different from the first metal layer and the second metal layer.

In some implementations, the conductive feature may include a top surface, a first bottom surface, and a second bottom surface. The first bottom surface may be vertically separated from the top surface by a first height. The second bottom surface may be laterally proximate the first bottom surface and vertically separated from the top surface by a second height that is different from the first height. In some implementations, the second bottom surface may be laterally adjacent to the first bottom surface. In some implementations, the first metal layer may extend vertically between the top surface and the first bottom surface. The second metal layer may extend vertically between the top surface and the second bottom surface. The third metal layer may extend vertically between the first metal layer and the first bottom surface. In some implementations, the third metal layer may include a metal silicide.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flowchart of an example method of fabricating a semiconductor structure, in accordance with some implementations.

FIGS. 2A, 2B, 2C, 2D, 2E, and 2F each illustrate a cross-sectional view of an example semiconductor structure at intermediate steps of the method illustrated in FIG. 1, in accordance with some implementations.

FIGS. 3A, 3B, 3C, 3D, 3E, 3F, and 3G each illustrate a cross-sectional view of an example semiconductor structure at intermediate steps of the method illustrated in FIG. 1, in accordance with some implementations.

FIGS. 4A, 4B, 4C, 4D, 4E, 4F, and 4G each illustrate a cross-sectional view of an example semiconductor structure at intermediate steps of the method illustrated in FIG. 1, in accordance with some implementations.

FIGS. 5A, 5B, 5C, 5D, 5E, and 5F each illustrate a cross-sectional view of an example semiconductor structure at intermediate steps of the method illustrated in FIG. 1, in accordance with some implementations.

FIG. 6 illustrates a flowchart of an example method of fabricating a semiconductor structure, in accordance with some implementations.

FIGS. 7A, 7B, 7C, 7D, 7E, 7F, 7G, and 7H each illustrate a cross-sectional view of an example semiconductor structure at intermediate steps of the method illustrated in FIG. 6, in accordance with some implementations.

FIG. 8 illustrates a cross-sectional view of an example semiconductor structure in accordance with some implementations.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used or other changes may be made without departing from the spirit or scope of the present disclosure. The illustrative embodiments described in the detailed description are not meant to be limiting of the subject matter presented.

The present disclosure provides embodiments of a method for patterning a semiconductor layer utilizing a selective surface modification scheme to obtain etch-resistant regions in the semiconductor layer. As a result of achieving etching selectivity, various regions of the semiconductor layer may be removed at different rates, thereby affording opportunities to form features of different depths (or heights) as well as to mitigate etching lag caused by features of different critical dimensions (CDs), all without needing to implement multiple etch-stop layers. In various implementations, a degree of etching selectivity provided by a surface modification layer disclosed herein may be tuned by adjusting properties including, for example, a composition and/or a thickness of the surface modification layer.

Advantageously, the methods disclosed herein may be readily implemented with existing fabrication techniques without requiring substantial integration changes, which may not be feasible or desirable in manufacturing settings. In addition, the methods disclosed herein may help mitigate etching lag caused by differences in feature sizes (e.g., critical dimensions, or CDs) without requiring additional films (e.g., etch-stop layers) or changes to etching recipes. Furthermore, the methods disclosed herein may be tuned to control properties (e.g., composition and thickness) of the surface modification layer, allowing the etching resistance and selectivity be tuned based on desired feature sizes and/or profiles. For example, the surface modification layer may be formed from a metal silicide, which can be further oxidized to form a metal oxide having a different degree of etching selectivity relative to silicon when compared to the metal silicide. Still further, the surface modification layer disclosed herein may be selectively removed by a plasma-less etching process, making the surface modification layer a desirable, non-destructive sacrificial protective layer.

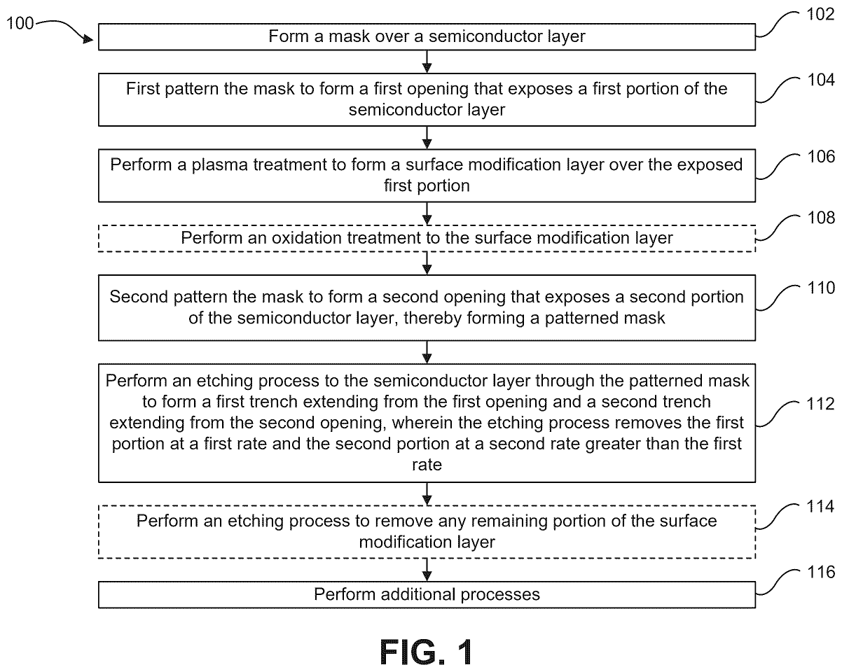

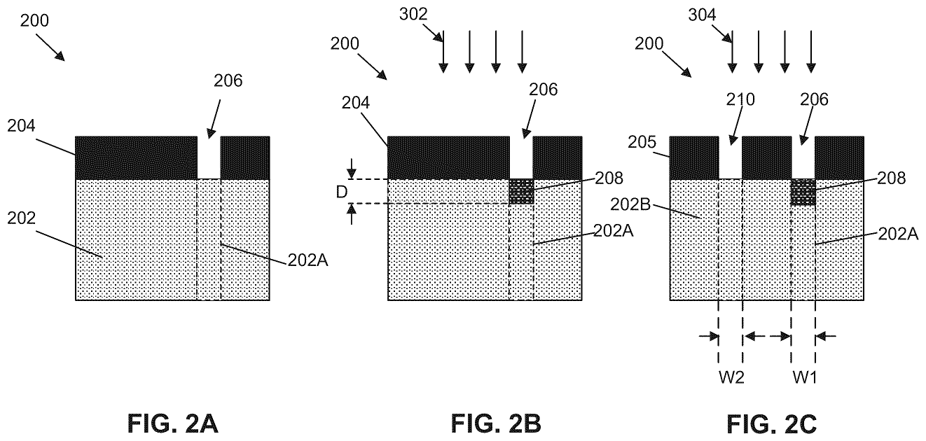

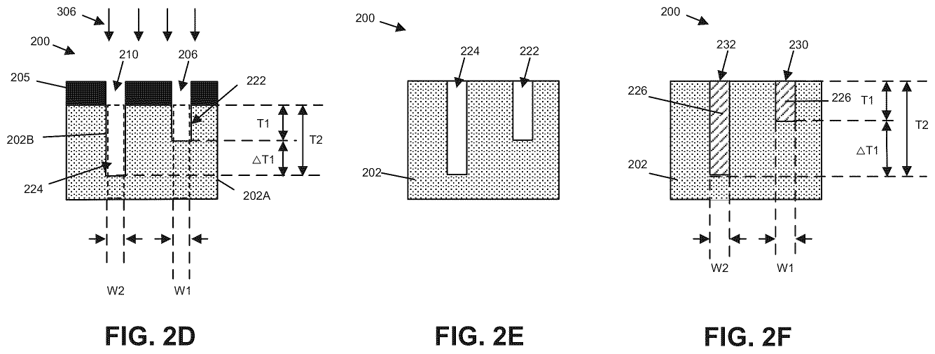

FIG. 1 illustrates a flowchart of an example method 100 for fabricating a semiconductor structure 200, according to some implementations of the present disclosure. The method 100 is described in reference to FIGS. 2A-2F, 3A-3G, 4A-4G, and 5A-5F, which illustrate cross-sectional views of a semiconductor structure 200 during intermediate steps of the method 100, according to some implementations of the present disclosure. It is noted that the method 100 is merely an example and is not intended to limit the present disclosure. It is further understood that additional operations may be provided before, during, and after each of the method 100 and that some other operations may only be briefly described herein.

Referring to FIGS. 1 and 2A, the method 100 at operation 102 forms a mask 204 over a semiconductor layer 202, which is a component of a semiconductor structure 200.

The semiconductor layer 202 includes a semiconductor material, such as a bulk semiconductor, a semiconductor-on-insulator (SOI), or the like, which may be doped (e.g., with a p-type or an n-type dopant) or undoped. The semiconductor layer 202 may include other semiconductor materials, such as a multi-layered or gradient semiconductor material. In some examples, the semiconductor layer 202 may include silicon (Si); germanium (Ge); a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; other suitable materials; or combinations thereof. In various implementations, the semiconductor layer 202 is a Si-based (or Si-containing) substrate that corresponds to a portion of a wafer, such as a Si wafer. Alternatively, in some implementations, the semiconductor layer 202 is configured as a component disposed over and separated from a semiconductor substrate (or wafer). In various implementations, the semiconductor layer 202 is substantially free of any metal elements.

In some implementations, the semiconductor layer 202 includes active regions (not depicted) configured to provide a number of device features (e.g., transistors, diodes, resistors, etc.; not depicted) in and/or over the semiconductor layer 202. Example transistors may include field-effect transistors (FETs), such as fin-like FET (e.g., FinFET), multi-gate FETs, nanosheet FETs, the like, or combinations thereof. The device features may include doped or undoped semiconductor materials, which may be similar in composition as the semiconductor layer 202.

In various implementations, the mask 204 includes a patternable material, such as a photoresist material and is formed by a deposition process over the semiconductor layer 202. For example, the mask 204 may be deposited by spin coating a photoresist material over the semiconductor layer 202. In various implementations, the mask 204 is patternable using a series of techniques including lithograph (e.g., photolithography) and etching. Generally, the mask 204 can be patterned by exposing (or irradiating) the photoresist material to a suitable light source (e.g., ultraviolet (UV), extreme ultraviolet (EUV), etc.) through a photomask and developing the exposed photoresist layer to form a patterned mask (e.g., patterned mask 205 depicted in FIG. 2D). The developing process removes portion(s) of the exposed photoresist layer based on chemical interactions between the exposed photoresist material and a solvent (e.g., a developer) used during the developing process. The patterned mask may then be used to further process (e.g., etch) the underlying semiconductor layer 202. For example, the pattered mask may be used to etch the semiconductor layer 202 using a suitable etching process. After processing the semiconductor layer 202, the patterned mask may be removed by a suitable method, such as resist stripping or plasma ashing.

Still referring to FIGS. 1 and 2A, the method 100 at operation 104 patterns the mask 204 to form a first opening 206 that exposed a first portion 202A of the semiconductor layer 202.

The mask 204 may be patterned using any suitable photolithography techniques described briefly above. For example, the mask 204 is exposed (or irradiated) to a light source through a photomask, resulting in a latent image in the mask 204. Generally, the latent image is composed of exposed portions and unexposed portions of the mask 204, which differ in chemical properties as a result the photoresist material's interaction with the light source. Subsequently, the latent pattern in the exposed mask 204 is developed to form the mask 204. In the present implementations, the resulting mask 204 includes the first opening 206 disposed at a location that corresponds to the first portion 202A of the semiconductor layer 202. In other words, the first opening 206 exposes the first portion 202A, while other portions of the semiconductor layer 202 remain under the mask 204.

Referring to FIGS. 1 and 2B, the method 100 at operation 106 performs a plasma treatment 302 to form a surface modification layer 208 in or over the first portion 202A of the semiconductor layer 202, where the surface modification layer 208 differs from the semiconductor layer 202 in composition.

In the present implementations, performing the plasma treatment 302 includes applying a plasma over the semiconductor structure 200 such that the first portion 202A of the semiconductor layer 202 is selectively exposed to the plasma, while other portions of the semiconductor layer 202 are blocked, or substantially blocked, from interacting with the plasma applied during the plasma treatment 302.

In various implementations, the plasma includes at least a metal-containing component configured to chemically react with a composition (e.g., silicon) of the semiconductor layer 202 in the first portion 202A, resulting in the surface modification layer 208. In some implementations, the metal-containing component includes a metal element selected from, for example, tungsten (W), molybdenum (Mo), the like, or combinations thereof. In some implementations, the metal-containing component further includes a non-metal element, such as a halogen, selected from, for example, fluorine (F), chlorine (Cl), the like, or combinations thereof. In some implementations, the metal-containing component includes a metal element and a halogen such that the metal-containing component includes a metal halide, including, for example, tungsten hexafluoride (WF₆), tungsten hexachloride (WCl₆), molybdenum hexafluoride (MoF₆), molybdenum hexachloride (MoCl₆), the like, or combinations thereof. In some implementations, the plasma includes additional species (e.g., gases) configured to accommodate the reaction between the metal-containing component and the first portion 202A.

In various implementations, the metal-containing component (e.g., the metal halide) chemically reacts with the composition of the semiconductor layer 202 to form the surface modification layer 208 in the first portion 202A. The surface modification layer 208 thus includes a metal silicide having a composition that is different from the semiconductor layer 202. In this regard, the surface modification layer 208 may be alternatively referred to as a metal silicide layer 208. In various implementations, the composition of the metal silicide in the surface modification layer 208 corresponds to that of the metal-containing component of the plasma treatment 302. For example, the metal silicide includes the metal element provided by the metal-containing component, and the silicon provided by the semiconductor layer 202 in the first portion 202A. In some examples, the surface modification layer 208 includes tungsten silicide (WSi), molybdenum silicide (MoSi), the like, or a combination thereof, depending on the type of metal-containing component used in the plasma treatment 302.

For embodiments in which the metal-containing component includes WF₆, performing the plasma treatment 302 causes WF₆ to react with Si and form WSi according to Reaction I below. It is noted that Reaction I only schematically illustrates the main reaction between the plasma (i.e., WF₆) applied during the plasma treatment 302 and the first portion 202A (i.e., Si) and is not intended to detail any intermediate or concurrent reactions that may also occur during the formation of WSi. Furthermore, any secondary and/or by-product resulting from the Reaction I are also omitted for purposes of simplicity.

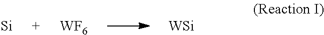

In some implementations, the surface modification layer 208 is formed over a top surface of the first portion 202A, i.e., as an adlayer. Alternatively, the surface modification layer 208 is formed within the first portion 202A. In some implementations, performing the plasma treatment 302 includes removing a topmost portion of the first portion 202A before, during, and/or after forming the surface modification layer 208. For example, the plasma treatment 302 may implement the plasma having an etching component to remove the topmost portion of the first portion 202A and subsequently implement the plasma having the metal-containing component to deposit the WSi layer over the etched first portion 202A. Regardless of the manner by which the surface modification layer 208 is formed, various parameters of the plasma treatment 302 may be adjusted to control properties, such as a thickness D, of the surface modification layer 208. As will be described in detail below, the thickness D of the surface modification layer 208 may contribute to a degree of etching selectivity between the first portion 202A and a second portion 202B of the semiconductor layer 202.

Referring to FIGS. 1 and 2C, the method 100 at operation 110 patterns the mask 204 to form a second opening 210 that exposes the second portion 202B of the semiconductor layer 202.

After performing the plasma treatment 302, the mask 204 is patterned again to form the second opening 210 having a location that corresponds to the second portion 202B of the semiconductor layer 202. In other words, the second opening 210 exposes the second portion 202B, while other portions of the semiconductor layer 202, including the first portion 202A, remain under the mask 204. In some implementations, as depicted herein, the second opening 210 is laterally proximate the first opening 206. In the present disclosure, the term “proximate” may be used interchangeably with the term “adjacent to” and may refer to close proximity between features. In some instances, “proximate” may refer to features disposed immediately next to (or adjacent to) one another with or without physical contact. Alternatively, “proximate” may refer to features disposed near but are separated from one another.

As depicted herein, patterning the mask 204 to form the second opening 210 is implemented using a patterning process 304. The patterning process 304 is generally similar to the patterning process implemented at operation 104 with the exception that a different photomask may be used to expose the mask 204, causing in the second opening 210 to be formed at a location that corresponds to the second portion 202B of the semiconductor layer 202. In the depicted implementations, the first opening 206 is formed to a first width W1 and the second opening 210 is formed to a second width W2, where the first width W1 is substantially the same as the second width W2. In various implementations, the first width W1 and the second width W2 define a width of the first portion 202A and a width of the second portion 202B, respectively, of the semiconductor layer 202. After forming the second opening 210 in the mask 204 using the patterning process 304, the mask 204 is considered a patterned mask 205 and may subsequently be used to further process the underlying semiconductor layer 202.

Referring to FIGS. 1, 2D, and 2E, the method 100 at operation 112 performs an etching process 306 to the semicondutor layer 202 through the patterned mask 205.

In various implementations, performing the etching process 306 includes applying a first etchant to remove portions of the semiconductor layer 202 exposed by the patterned mask 205. As depicted herein, the etching process 306 removes the first portion 202A and the second portion 202B of the semiconductor layer 202, while other portions of the semicondutor layer 202 protected by the patterned mask 205 remain substantially unetched. After performing the etching process 306, the patterned mask 205 is removed by a suitable method, such as plasma ashing or resist stripping, as depicted in FIG. 2E.

In various implementations, the etching process 306 includes a plasma-based etching process, such as a reactive ion etching (RIE) process. In this regard, the first etchant may include ions (reactive ion species) capable of chemically reacting with the composition of the semiconductor layer 202. In some implementations, the first etchant includes an ionized fluorine-containing gas, such as a fluorocarbon-containing gas, a hydrofluorocarbon-containing gas, the like, or combinations thereof. For example, the first etchant may include an ionized fluorine-containing gas having a chemical formula CHₓF_{y}, where x≥0, y>0, and values of x and y satisfy stoichiometric ratios suitable for a given chemical formula. Non-limiting examples of the fluorine-containing gas with such chemical formula may include CF₄, CHF₃, CH₃F, CH₂F₂, or the like. In some implementations, the first etchant includes an ionized fluorine-containing gas having one or more non-carbon atoms. For example, the fluorine-containing gas may include SF₆, SiF₄, NF₃, the like, or combinations thereof. Additionally or alternatively, the first etchant may include an ionized chlorine-containing gas, such as SiCl₄, Cl₂, BCl₃, the like, or combinations thereof. Other ionized gases may also be implemented as the first etchant according to implementations of the present disclosure. In some implementations, the first etchant may additionally include a carrier gas, a diluent gas, or a combination thereof. For example, the first etchant may include argon (Ar).

Referring to FIG. 2D, the etching process 306 removes the first portion 202A to form a first trench 222 and removes the second portion 202B to form a second trench 224, where the first trench 222 and the second trench 224 extend vertically from the first opening 206 and the second opening 210, respectively. In the present implementations, the etching process 306 removes the first portion 202A and the second portion 202B at different rates, which are each defined as an amount of the semiconductor layer 202 being etched or removed by the first etchant per unit time. Specifically, the first trench 222 is formed to a first depth T1 and the second trench 224 is formed to a second depth T2 that is greater than the first depth T1, suggesting that a first rate at which the first portion 202A is removed is less than a second rate at which the second portion 202B is removed. Such a difference in etching rate (or removal rate) can be described by a difference ΔT1 between the first depth T1 and the second depth T2 when the first width W1 of the first trench 222 (or the first opening 206) is substantially the same as the second width W2 of the second trench 224 (or the second opening 210).

In various implementations, the difference in etching rate is attributed to the presence of the surface modification layer 208 selectively formed over the first portion 202A but not over the second portion 202B. As described herein, the surface modification layer 208 includes a metal silicide, where the metal element is provided by the metal-containing component in the plasma applied during the plasma treatment 302. In other words, the composition of the surface modification layer 208 is distinctly different from that of the semiconductor layer 202, which is substantially free from any metal element. In one such example, referring to FIG. 2C again, the semiconductor layer 202 in the second portion 202B includes Si and is substantially free of any metal element, and the surface modification layer 208 includes a metal silicide, such as WSi, formed from a plasma of WF₆ applied to the semiconductor layer 202 during the plasma treatment 302.

Because the first etchant is configured to selectively remove the semiconductor layer 202, the presence of the surface modification layer 208 hinders or impedes the removal of the underlying first portion 202A relative to the second portion 202B, which is directly exposed to the first etchant. In other words, an etching selectivity between the first portion 202A and the second portion 202B is increased due to the addition of the surface modification layer 208 over the first portion 202A. Accordingly, when the etching process 306 is applied to the semiconductor structure 200, the second portion 202B is removed at the second rate that is higher than the first rate at which the first portion 202A is removed. Accordingly, the resulting first trench 222 and the second trench 224, while substantially equal in width, are formed to different depths.

In some implementations, the first rate may change based on the degree of etching selectivity provided by the surface modification layer 208. In some implementations, factors influencing the degree of etching selectivity provided by the surface modification layer 208 include, for example, the composition of the surface modification layer 208 and the thickness D of the surface modification layer 208. For example, to enhance the etching selectivity and further reducing the first rate, the thickness D of the surface modification layer 208 may be increased during the plasma treatment 302.

In some implementations, as depicted in FIG. 2D, performing the etching process 306 causes the surface modification to be removed completely from the first trench 222, such that the semiconductor layer 202 is exposed in both the first trench 222 and the second trench 224.

Referring to FIGS. 1 and 2F, the method 100 at operation 116 may perform additional processes. For example, the method 100 may deposit a conductive material 226 (e.g., a metal) over the semiconductor structure 200 to fill the first trench 222 and the second trench 224. In some implementations, the conductive material 226 includes any suitable metal, such as W, Mo, copper (Cu), aluminum (Al), titanium (Ti), tantalum (Ta), ruthenium (Ru), the like, or combinations thereof. In some implementations, the conductive material 226 includes W. In some implementations, the conductive material 226 has a multi-layered structure that includes more than one sub-layer of different conductive materials. Portions of the conductive material 226 formed over the semiconductor layer 202 may then be polished by a suitable process, such as a chemical-mechanical polishing/planarization (CMP) process, resulting in a first conductive feature 230 and a second conductive feature 232 in the first trench 222 and the second trench 224, respectively. Subsequently, portions of the semiconductor layer 202 (e.g., portions disposed below the second conductive feature 232 depicted in FIG. 2F) may be polished to expose the first conductive feature 230 and/or the second conductive feature 232. In this regard, one or both of the first conductive feature 230 and the second conductive feature 232 may be configured as through-substrate/silicon vias (TSV) in the semiconductor layer 202.

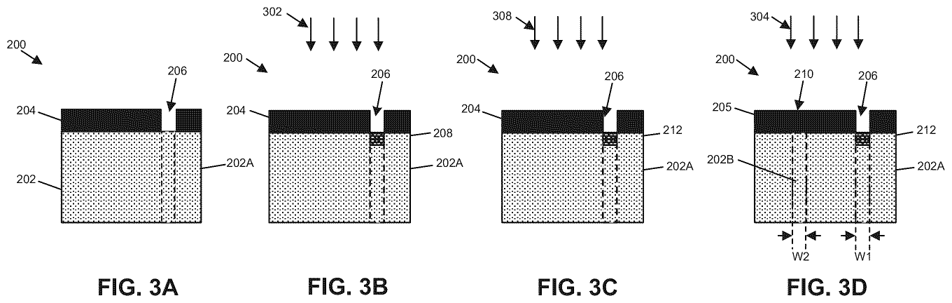

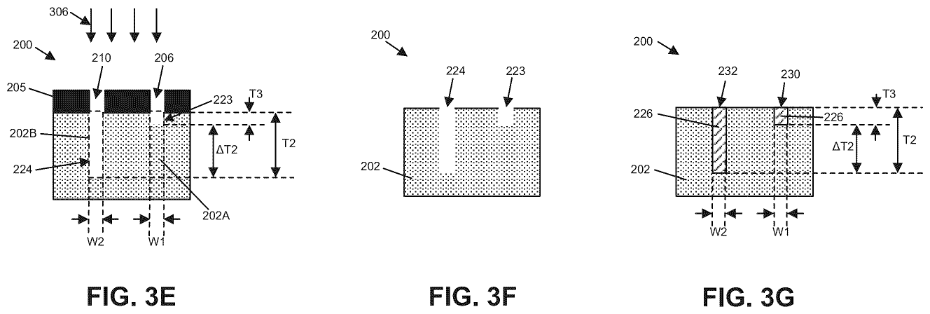

In some implementations, the surface modification layer 208 can be further treated to enhance the etching selectivity between the first portion 202A and the second portion 202B. For example, referring to FIGS. 1 and 3A-3C, after forming the mask 204 at operation 102, patterning the mask 204 at operation 104, and performing the plasma treatment 302 at operation 106, which are similar to those depicted in FIGS. 2A and 2B, the method 100 at operation 108 performs an oxidation treatment 308 to the surface modification layer 208. The oxidation treatment 308 applies oxygen (e.g., oxygen gas) to the exposed surface modification layer 208, thereby causing the metal silicide in the surface modification layer 208 to form a metal oxide. Continuing with the example of WSi as the metal silicide in the surface modification layer 208, performing the oxidation treatment 308 results in the formation of tungsten oxide (WO₃) in the surface modification layer 208 according to Reaction II below.

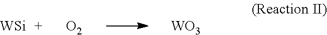

Similar to the description of Reaction I above, Reaction II only schematically illustrates the main reaction between oxygen (i.e., O₂) and the metal silicide (i.e., WSi) of the surface modification layer 208 and is not intended to detail any intermediate or concurrent reactions that may also occur during the formation of WO₃. Furthermore, any secondary and/or by-product resulting from the Reaction II are also omitted for purposes of simplicity.

Subsequently, referring to FIGS. 1 and 3D-3F, the method 100 proceeds to operations 110 and 112 to pattern the mask 204 and perform the etching process 306, respectively, resulting in a third trench 223 and the second trench 224 with locations that correspond to the first opening 206 and the second opening 210, respectively. Due to the enhanced etching selectivity provided by the oxidized surface modification layer 208, the etching process 306 removes the first portion 202A at a third rate that is lower than the first rate at which the etching process 306 removes the first portion 202A as depicted in FIG. 2D. Assuming the same etching conditions are applied, the etching process 306 removes the second portion 202B at the same second rate as depicted in FIG. 2D, such that the second trench 224 has the depth T2 as described above. Accordingly, a difference ΔT2 between the depth T2 and the depth T3 is greater than the difference ΔT1, reflecting the enhanced etching selectivity caused by the oxidized surface modification layer 208. After performing the etching process 306, the patterned mask 205 is removed from the semiconductor structure 200 by a suitable method, such as plasma ashing or resist stripping.

Thereafter, referring to FIGS. 1 and 3G, the method 100 removes the patterned mask 205 from the semiconductor structure 200 and proceeds to operation 116 to perform additional operations similar to that depicted in FIG. 2F. The resulting first conductive feature 230 has the first width W1 and the third depth T3, and the second conductive feature 232 has the second width W2 and the second depth T2, where the first width W1 and the second width W2 are substantially the same and the second depth T2 is greater than the third depth T3.

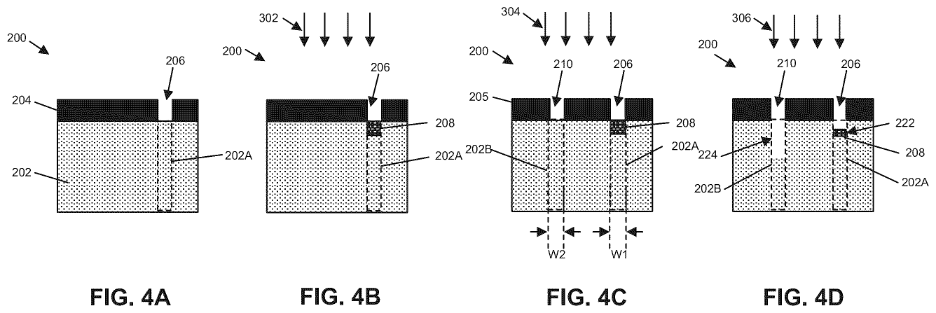

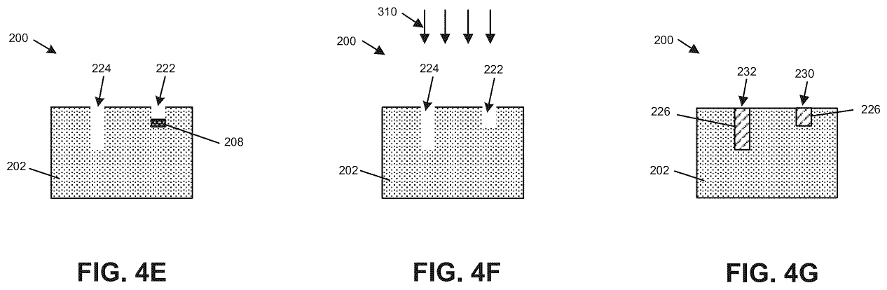

In some implementations, performing the etching process 306 does not completely remove the surface modification layer 208. As a result, an additional etching process may be performed after performing the etching process 306 to remove the surface modification layer 208 without removing, or substantially removing, any portions of the semiconductor layer 202. For example, referring to FIGS. 1 and 4A-4F, after forming the mask 204 at operation 102, patterning the mask 204 at operation 104, performing the plasma treatment 302 at operation 106, and performing the etching process 306 at operation 112, which are similar to those depicted in FIGS. 2A-2E, the method 100 at operation 114 performs an etching process 310 to remove any remaining portions of the surface modification layer 208 from the first trench 222.

In some implementations, the etching process 310 differs from the etching process 306 in that the etching process 310 includes a plasma-less etching process. In other words, performing the etching process 310 includes applying a second etchant that is free from any reactive ion species. In addition, the second etchant is configured to selectively remove the surface modification layer 208 without removing, or substantially removing, other portions of the semiconductor structure 200. In this regard, the etching process 310 may be implemented without using any mask. In some implementations, the etching process 310 is optional such that the remaining portion of the surface modification layer 208 is not removed from the first trench 222.

Subsequently, referring to FIGS. 1 and 4G, the method 100 proceeds to operation 116 to perform additional operations similar to that depicted in FIG. 2F.

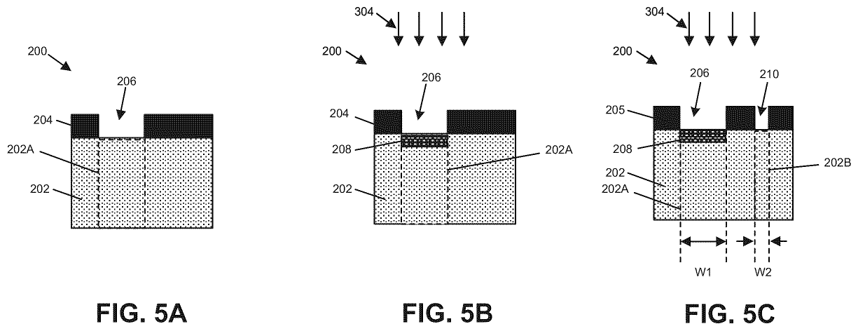

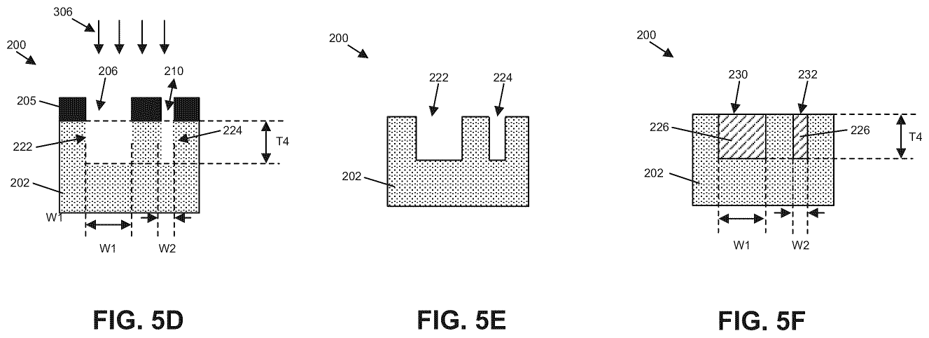

FIGS. 5A-5F collectively illustrate another embodiment of the method 100 similar to the embodiment depicted in FIGS. 2A-2F. For example, referring to FIGS. 1 and 5A, the method 100 at operation 102 forms the mask 204 over the semiconductor layer 202 and at operation 104 patterns the mask 204 to form the first opening 206 that exposes and defines the first portion 202A. Referring to FIGS. 1 and 5B, the method 100 at operation 106 performs the plasma treatment 302 to form the surface modification layer 208 over the first portion 202A.

Referring to FIGS. 1 and 5C, the method 100 at operation 110 patterns the mask 204 again to form the second opening 210, resulting in the patterned mask 205. The second opening 210 exposes and defines the second portion 202B of the semiconductor layer 202 as described here. In the depicted implementations, the first opening 206 is formed to the first width W1 and the second opening 210 is formed to the second width W2, where the first width W1 is greater than the second width W2.

Referring to FIGS. 1, 5D, and 5E, the method 100 at operation 112 performs the etching process 306 to the semiconductor layer 202 through the patterned mask 205. The resulting first trench 222, which extends from the first opening 206, has the first width W1, and the second trench 224, which extends from the second opening 210, has the second width W2. Similar to the embodiment depicted in FIGS. 2D and 2E, the presence of the surface modification layer 208 alters the rate at which the etching process 306 removes the first portion 202A relative to the second portion 202B. Specifically, the etching process 306 removes the first portion 202A at the first rate and removes the second portion 202B at the second rate that is greater than the first rate. However, the retardation in the etching rate of the first portion 202A caused by the surface modification layer 208 can offset, at least partially, an etching lag (e.g., a RIE lag) effect caused by disparity in the widths (e.g., CDs) of the trenches 222 and 224. Accordingly, by incorporating the surface modification layer 208 and controlling dimensions of the openings in the mask 204, the etching rates of the first portion 202A and the second portion 202B can be tuned such that the first trench 222 and the second trench 224 can be formed to substantially the same depth T4. After performing the etching process 306, which may also remove the surface modification layer 208, the patterned mask 205 is removed from the semiconductor structure 200 by a suitable method, such as plasma ashing or resist stripping.

Thereafter, referring to FIGS. 1 and 5F, the method 100 removes the patterned mask 205 from the semiconductor structure 200 and proceeds to operation 116 to perform additional operations similar to that depicted in FIG. 2F. The resulting first conductive feature 230 and the second conductive feature 232 have substantially the same depth T4 but different widths, where the first width W1 of the first conductive feature 230 is greater than the second width W2 of the second conductive feature 232.

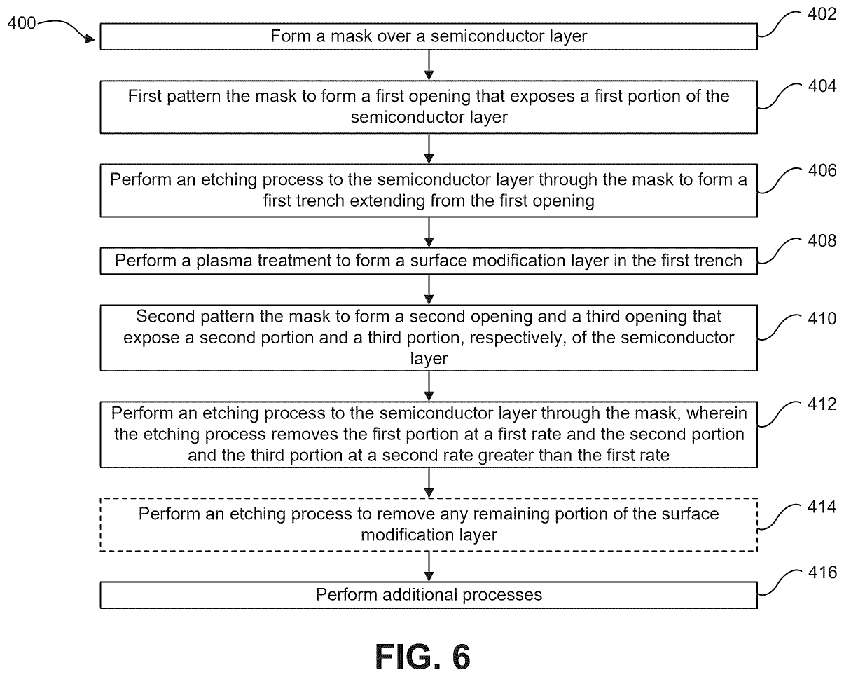

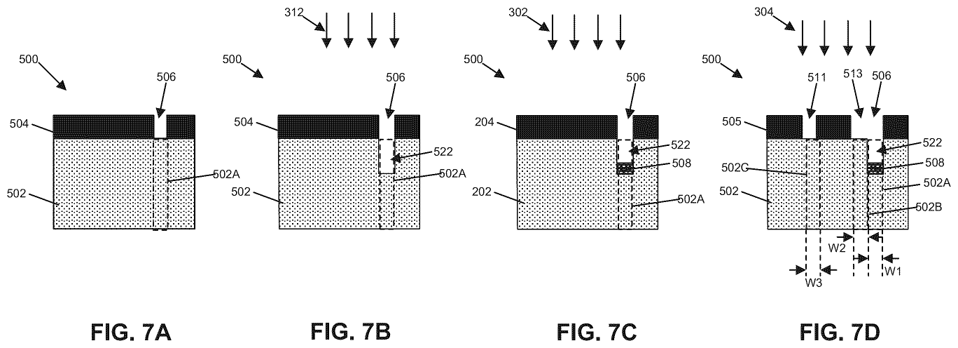

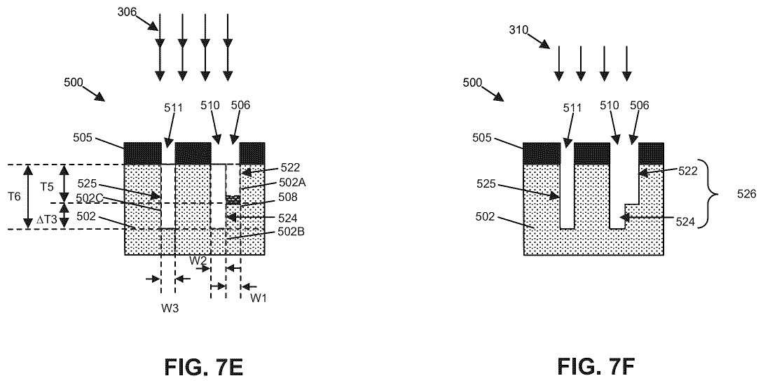

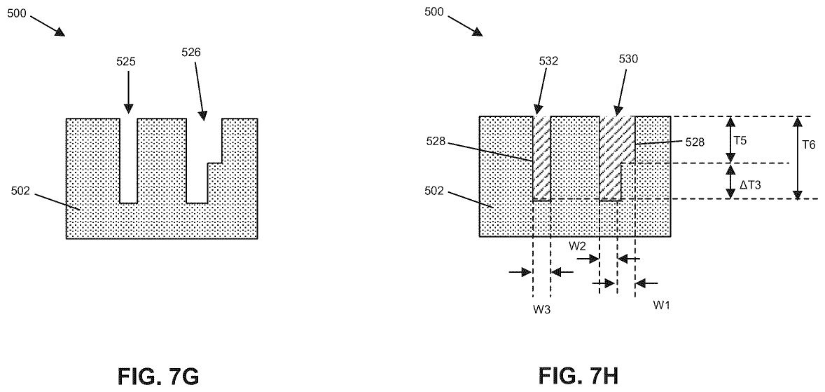

FIG. 6 illustrates a flowchart of an example method 400 for fabricating a semiconductor structure 500, according to some implementations of the present disclosure. The method 400 is described in reference to FIGS. 7A-7H, which illustrate cross-sectional views of a semiconductor structure 500 during intermediate steps of the method 400, according to some implementations of the present disclosure. It is noted that the method 400 is merely an example and is not intended to limit the present disclosure. It is further understood that additional operations may be provided before, during, and after each of the method 400 and that some other operations may only be briefly described herein. Some operations of the method 400 may be similar to those of the method 100 and details of such operations are thus omitted for purposes of brevity.

Referring to FIGS. 6 and 7A, the method 400 at operation 402 forms a mask 504 over a semiconductor layer 502 and at operation 404 patterns the mask 504 to form a first opening 506 that exposes and defines a first portion 502A in the semiconductor layer 502. Referring to FIGS. 6 and 7B, the method 400 at operation 406 performs an etching process 312, which is similar to the etching process 306 of FIG. 2D, to the semiconductor layer 502 through the mask 504 to form a first trench 522 extending from the first opening 506. Referring to FIGS. 6 and 7C, the method 400 at operation 408 performs the plasma treatment 302 to form a surface modification layer 508 over the first portion 502A. In this regard, the surface modification layer 508 is formed within the first trench 522 and below a top surface of the semiconductor layer 502. The surface modification layer 508 is similar to the surface modification layer 208 of FIG. 2B in that it has a composition distinctly different from that of the semiconductor layer 502, thereby enhancing etching selectivity of the first portion 502A relative to other portions of the semiconductor layer 502.

Referring to FIGS. 6 and 7D, the method 400 at operation 410 patterns the mask 504 to form a second opening 510 and a third opening 511 that expose and define a second portion 502B and a third portion 502C, respectively, in the semiconductor layer 502 using the patterning process 304. In the depicted implementations, the first opening 506 and the second opening 510 are laterally connected with one another, while the third opening 511 is laterally proximate and separated from the second opening 510. In the depicted implementations, the first opening 506 has the first width W1, the second opening 510 has the second width W2, and the third opening 511 has a third width W3, where the first width W1, the second width W2, and the third width W3 are substantially the same. After performing the patterning process 304 at operation 410, the mask 504 is considered a patterned mask 505.

Referring to FIGS. 6 and 7E, the method 400 at operation 412 performs the etching process 306 to the semiconductor layer 502 through the patterned mask 505. The etching process 306 removes the first portion 502A, the second portion 502B, and the third portion 502C, thereby extending the first trench 522 as well as forming a second trench 524 that extends from the second opening 510 and a third trench 525 that extends from the third opening 511. Similar to the embodiment depicted in FIG. 2D, the etching process 306 removes the first portion 502A at a rate that is less than a rate that it removes the second portion 502B and the third portion 502C. In this regard, the presence of the surface modification layer 508 alters the etching selectivity of the first portion 502A relative to the second portion 502B and the third portion 502C. Furthermore, because the first trench 522, the second trench 524, and the third trench 525 have substantially the same widths, the lower etching rate of the first portion 502A causes the first trench 522 to have a depth T5 that is less than a depth T6 of each of the second trench 524 and the third trench 525. A difference ΔT3 between the depth T5 and the depth T6 is indicative of the extent of etching selectivity provided by the surface modification layer 508.

In the depicted implementations, a portion of the surface modification layer 508 remains in the first trench 522 after performing the etching process 306. As a result, referring to FIGS. 1 and 7F, the method 400 at operation 414 performs the etching process 310 to remove the remaining portion of the surface modification layer 508. The resulting first trench 522 and the second trench 524 coalesce to form a fourth trench 526 that has a step-like sidewall profile. Referring to FIG. 7G, the patterned mask 505 is subsequently removed from the semiconductor structure 500 by a suitable method, such as plasma ashing or resist stripping.

Thereafter, referring to FIGS. 6 and 7H, the method 400 at operation 416 performs additional operations similar to that depicted in FIG. 2F. For example, the method 400 may deposit a conductive material 528 (e.g., a metal) in the third trench 525 and the fourth trench 526 to form the first conductive feature 530 and the second conductive feature 232, respectively. The conductive material 528 may include a material similar to that of the conductive material 226 described herein. In the depicted implementations, the first conductive feature 530 includes a first portion having the depth T5 and a second portion having the depth T6, and the second conductive feature 532 has the depth T6.

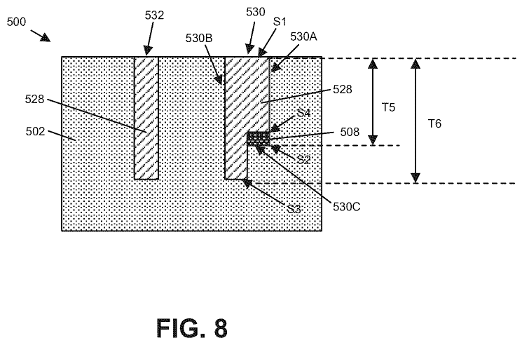

In some implementations, referring to FIG. 8, the method 400 may omit operation 414 such that the remaining portion of the surface modification layer 508 is not removed from the first trench 522. The conductive material 528 may then be deposited over the remaining portion of the surface modification layer 508, which becomes a bottom portion of the first conductive feature 530. In this regard, the first conductive feature 530 includes a first metal layer 530A disposed over a third metal layer 530C, and a second metal layer 530B laterally proximate both the first metal layer 530A and the third metal layer 530C. The first metal layer 530A and the second metal layer 530B have substantially the same composition and both include the conductive material 528, while the third metal layer 530C corresponds to the surface modification layer 508 (a remaining portion thereof) and thus has a composition different from that of the first metal layer 530A and the second metal layer 530B. In some implementations, the third metal layer 530C (i.e., the surface modification layer 508) includes a metal silicide, a metal oxide, the like, or combinations thereof. In one such example, the first metal layer 530A and the second metal layer 530B may both include W, while the third metal layer 530C may include WSi. In another such example, the first metal layer 530A and the second metal layer 530B may both include W, while the third metal layer 530C may include WO₃.

Structurally, the first metal layer 530A extends vertically between a top surface S1 and a first bottom surface S2 of the first conductive feature 530. The second metal layer 530B extends vertically between the top surface S1 and a second bottom surface S3 of the first conductive feature 530. The third metal layer 530C extends vertically between a bottom surface S4 of the first metal layer 530A and the first bottom surface S2 of the first conductive feature 530. As described herein, due to the etching selectivity provided by the surface modification layer 508, the depth T5 extending from the top surface S1 and the first bottom surface S2 (i.e., the depth T5 of the first trench 522 depicted in FIG. 7E) is less than the depth T6 extending from the top surface S1 and the second bottom surface S3 (i.e., the depth T6 of the second trench 524 depicted in FIG. 7E).

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
forming a mask over a semiconductor layer;
patterning the mask to form a first opening that exposes a first portion of the semiconductor layer;
performing a plasma treatment to form a surface modification layer over the exposed first portion;
patterning the mask to form a second opening that exposes a second portion of the semiconductor layer, thereby forming a patterned mask that defines the first and second openings; and
performing an etching process to the semiconductor layer through the patterned mask to form a first trench extending from the first opening and a second trench extending from the second opening, the etching process removing the first portion at a first rate and the second portion at a second rate that is greater than the first rate.

2. The method of claim 1, wherein:
first patterning the mask to form the first opening includes forming the first opening to a first width;
patterning the mask to form the second opening includes forming the second opening to a second width that is the same as the first width; and
performing the etching process results in the first trench having a first depth and the second trench having a second depth that is greater than the first depth.

3. The method of claim 1, wherein:
first patterning the mask to form the first opening includes forming the first opening to a first width;
patterning the mask to form the second opening includes forming the second opening to a second width that is the less than the first width; and
performing the etching process results in the first trench having a first depth and the second trench having a second depth that is the same as the first depth.

4. The method of claim 1, wherein:
performing a plasma treatment to form a surface modification layer includes applying a plasma of a metal halide including tungsten and fluorine; and
performing a plasma treatment to form a surface modification layer includes performing a plasma treatment to form a surface modification layer that includes tungsten and silicon.

5. The method of claim 1, wherein performing the etching process causes the surface modification layer to be removed from the first trench.

6. The method of claim 1, further comprising, after performing the etching process, performing a second etching process to remove the surface modification layer from the first trench.

7. The method of claim 1, further comprising performing an oxidation process to treat the surface modification layer before performing the etching process.

8. The method of claim 1, further comprising depositing a conductive layer to fill the first trench and the second trench.

9. A method, comprising:
forming a patterned mask over a semiconductor layer, the patterned mask defining a first opening to expose a first portion of the semiconductor layer;
performing a first etching process to the semiconductor layer through the patterned mask, resulting in a first trench in the semiconductor layer at the first portion;
applying a metal-containing plasma to form a metal silicide layer in the first trench at the first portion of the semiconductor layer;
forming a second opening in the patterned mask to expose a second portion of the semiconductor layer proximate the first trench; and
performing a second etching process to the semiconductor layer through the patterned mask to selectively remove the second portion of the semiconductor layer at a higher rate than removal of the first portion of the semiconductor layer.

10. The method of claim 9, wherein applying a metal-containing plasma includes applying a metal-containing plasma that includes a metal and a halogen, the metal including tungsten or molybdenum, and the halogen including fluorine or chlorine.

11. The method of claim 9, wherein performing the second etching process causes the metal silicide layer to be removed.

12. The method of claim 9, further comprising, after performing the second etching process, performing a third etching process to remove the metal silicide layer.

13. The method of claim 12, wherein:
performing the second etching process includes performing a plasma-based etching process; and
performing the third etching process includes performing a plasma-less etching process.

14. The method of claim 13, wherein performing the second etching process includes performing a reactive ion etching (RIE) process.

15. The method of claim 9, further comprising, before performing the second etching process, oxidizing the metal silicide layer to form a metal oxide layer in the first trench.

16. The method of claim 15, wherein applying a metal-containing plasma includes applying tungsten hexafluoride, the metal silicide layer including tungsten silicide, and the metal oxide layer including tungsten oxide.

17. The method of claim 9, wherein forming a second opening includes forming a second opening in the patterned mask to expose a second portion of the semiconductor layer proximate the first trench.

18. A semiconductor structure, comprising:
a semiconductor layer; and
a conductive feature embedded in the semiconductor layer, the conductive feature including:
a first metal layer,
a second metal layer in direct contact with the first metal layer, and
a third metal layer vertically below and in direct contact with the first metal layer, the second metal layer laterally proximate the first metal layer and the third metal layer, the first metal layer and the second metal layer having the same composition, and the third metal layer having a composition that is different from the first metal layer and the second metal layer.

19. The semiconductor structure of claim 18, wherein the conductive feature includes
a top surface,
a first bottom surface vertically separated from the top surface by a first height, and
a second bottom surface laterally proximate the first bottom surface and vertically separated from the top surface by a second height that is different from the first height, the first metal layer extending vertically between the top surface and the first bottom surface, the second metal layer extending vertically between the top surface and the second bottom surface, and the third metal layer extending vertically between the first metal layer and the first bottom surface.

20. The semiconductor structure of claim 18, wherein the third metal layer includes a metal silicide.
